(19) United States
(12) Patent Application Publication
(10) Pub. No.: US 2022/0022336 A1
(43) Pub. Date: Jan. 20, 2022

(54) PACKAGING UNIT FOR A SUBSTRATE

(71) Applicant: Heraeus Deutschland GmbH & Co. KG, Hanau (DE)

(72) Inventors: Hans-Jürgen Richter, Hanau (DE); Richard Wacker, Hanau (DE); Nadja Pelshaw, Hanau (DE); Yvonne Löwer, Hanau (DE)

(21) Appl. No.: 17/309,556

(22) PCT Filed: Nov. 21, 2019
(86) PCT No.: PCT/EP2019/082030

§ 371 Date: Jun. 4, 2021

(30) Foreign Application Priority Data
Dec. 6, 2018 (EP) 18210738.3

(51) Int. Cl. H05K 5/04; H05K 5/00; H05K 7/14

(52) U.S. Cl. CPC H05K 5/04; H05K 7/1427; H05K 5/0021

(57) ABSTRACT

The present invention relates to a packaging unit for a substrate, a package stack with such packaging units and a process for packaging a substrate. The packaging unit for a substrate comprises a first shell, a substrate and a second shell. The substrate is inserted into the first shell, and the second shell is mounted on the first shell so that a first side of the substrate is surrounded by the first shell and an opposite, second side of the substrate is covered by the second shell. A metal deposit is applied to the second side of the substrate and an adhesive point is arranged on the metal deposit. The second shell is supported on the first shell in such a way that the second shell is only in contact with the substrate outside the adhesive point.

### TECHNICAL DOMAIN

The present invention relates to a packaging unit for a substrate, a package stack with such packaging units and a process for packaging a substrate.

### BACKGROUND OF THE INVENTION

Due to their high thermal conductivity, high dimensional stability or mechanical strength and their high dielectric strength, ceramic circuit boards are of particular interest in the field of high-performance electronics.

DE 10 2010 018 668 B4 discloses a packaging unit of a package for metal-ceramic substrates and several metal-ceramic substrates, each comprising one ceramic layer, and of single metallisation formed on at least one surface side of the ceramic layer, and pre-determined break lines extending between these.

DE 10 2012 106 087 B4 discloses a packaging unit for substrates, in particular for metal-ceramic substrates, comprising a packaging with a packaging lower section made of a flat material and a holder formed in a recess of an upper base section of the lower section of the packaging unit for a plurality or at least one substrate stack or partial stack.

However, for sensitive substrates and, in particular, substrates with sensitive surfaces or surface sections, these packagings can still be improved.

### SUMMARY OF THE INVENTION

It is therefore the aim of the present invention to provide a packaging unit for substrates, with which sensitive substrates can also be securely packaged.

This aim is achieved by a packaging unit for a substrate, a package stack with a plurality of such packaging units and a process for packaging a substrate in accordance with the independent claims. Advantageous forms of embodiment and further developments are set out in the sub-claims and the following description.

The packaging unit for a substrate comprises a first shell, a substrate and a second shell. The substrate is inserted into in the first shell, and the second shell is mounted on the first shell so that a first side of the substrate is surrounded by the first shell and an opposite, second side of the substrate is covered by the second shell. A metal deposit is applied to the second side of the substrate and an adhesive point is arranged on the metal deposit. The second shell is supported on the first shell in such a way that the second shell is only in contact with the substrate outside the adhesive point.

The advantage of the packaging unit according to the invention lies in the fact that even sensitive substrates can be securely packed, and, in particular, be stacked in a space-saving manner, without touching the adhesive point on the metal deposit. The packaging unit according to the invention makes is possible for the metal deposit and the adhesive point to be applied by a manufacturer or further processor of the substrate to the substrate immediately after production of the substrate, and for the substrate with the metal deposit and adhesive point to be sent to a further processor or a user without problems. In this way, further processors or users of the substrate provided with a metal deposit and adhesive point can apply a further component directly onto the adhesive point of the substrate, and, for example by way of a soldering or sintering process, directly attach the component (without preliminary work in order to fasten the component). This so-called pre-application of the metal deposit and the adhesive point allows a further component to fastened on the substrate in a cost-effective manner At present, the substrates are generally manufactured and marketed without pre-applied metal or solder deposits. Therefore, it is not necessary to separate the substrates from one another other than by way of continuous films. However, in the case of a substrate with a pre-applied metal deposit, an adhesive point is applied to the substrate which must not smeared or touched during packaging and sending of the components. The first and the second shell can contribute to the substrates being able to be stacked, stored and/or transported in a space-saving manner without contacting the adhesive point.

The substrate can be any carrier material, which is not, for example, immediately fully processed, and therefore first has to be stored in a dependable way. The substrate can be planar in shape and have a flat, even structure. For example, in semiconductor technology, the substrate can be an initial material for the production of electronic modules. The substrate can be suitable for an electronic application, in which an electronic component, for example a chip, a switch, a lighting element, a capacitor, a resistor or suchlike is applied to the substrate.

On its surface, the substrate has a so-called metal deposit. The metal deposit, in other words a supply of metal, can, depending on the purpose of use, comprise or consist of one metal or several different metals in certain mixing ratios. The metal deposit can, for example, be suitable for a durable, fixed connection of components, for instance in that it combines or forms alloys with the surface of components and hardens after cooling, or combines with the surface of components as a sintering material without melting. The size and thickness of the metal deposit can also vary depending on the purpose of use.

An adhesive point is arranged on the metal deposit. The adhesive point can used for and be designed for fastening a, for example, electronic component onto the substrate in order to facilitate a subsequent soldering or sintering process between the electronic component and the substrate. During soldering or sintering of the electronic component with the substrate, the adhesive point can vaporise undecomposed and/or decompose and volatilise so that the adhesive point does not leave any, or no interfering residues behind.

The planar-shaped substrate can have a first and a second side, which can respectively be designated as the underside and upper side. The “underside” can be a surface of the substrate on which neither a metal deposit nor an adhesive point is placed. In contrast to this, an “upper side” can be a surface of the substrate on which the metal deposit and the adhesive point are applied.

The packaging unit comprises a first and a second shell. At least one of the first and second shells can tub-shaped in order to receive the substrate in the interior space of the shell. In this way, the first side, or underside of the substrate, can be surrounded by the first shell. The second shell can be mounted on the first shell in which the substrate is placed. In other words, the first and second shell can be stacked on top of each other in the vertical direction and the substrate can be positioned between two consecutive shells. Thus, a base of the second shell can cover the second side, or upper side, of the substrate.

The second shell is supported on the first shell in such a way that the second shell is only in contact with the substrate outside the adhesive point. In other words, the second shell does not come into contact with the adhesive point, neither laterally nor on the upper side of the adhesive point. In this way it is achieved that the adhesive point is not contacted or smeared. The second shell can also be placed on the first substrate in such a way that it is only in contact with the first substrate outside the metal deposit. Preferably, the second shell does not come into contact with the metal deposit, either laterally or on the upper side of the metal deposit. In this way it is achieved that the metal deposit is also not contacted.

In one form of embodiment the substrate is a metal-ceramic substrate. In one form of embodiment the metal-ceramic substrate comprises a ceramic layer and at least one metallisation layer, wherein the metal deposit is applied onto the metallisation layer. In one form of embodiment the metal-ceramic substrate comprises the ceramic layer and two metallisation layers, wherein the metal deposit is applied onto one of the metallisation layers. In one form of embodiment, the metal-ceramic substrate comprises a ceramic layer and two metallisation layers, and both metallisation layers have an outer surface onto which the metal deposit is applied.

The term “metal-ceramic substrate” can be taken to mean that the substrate is made of ceramic and can be metallised through various processes, for example, direct copper bonding (usually designated DCB processes), direct aluminium bonding (usually designate DAB processes) or active metal brazing (usually designated as AMB processes). Suitable materials for the ceramic structure are, for example, an oxide, a nitride, a carbide, or a mixture or composite of at least two of these materials, more particularly, possibly, doped aluminium oxide or silicon nitride ceramic. The composite material obtained after the metallisation of the ceramic substrate is also known as a metal-ceramic substrate or metal-ceramic composite. If, for example, it is produced through a DCB process, the term “DCB substrate” is also often used.

Metallisation of the ceramic substrate can, for example, be brought about through initially oxidising a metal foil, so that a metal oxide layer is produced on its surface. The oxidised metal foil is placed on the ceramic substrate and the ceramic substrate is heated with the oxidised metal foil.

The substrate can be a direct copper bonding (DCB) or a direct aluminium bonding (DAB) substrate which allows a good electrical and thermal connection of electronic components and chips via copper or aluminium respectively.

In the case of a solderable material, the metal deposit can be applied to the metal ceramic substrate through soldering, for example vacuum soldering in an active atmosphere with formic acid activation. In the case of a sinterable metal, the metal deposit can be applied through sintering, or sintering onto the metal ceramic substrate. The metal deposit can be applied to the metal ceramic substrate in a defined volume, at a defined position and with a defined shape. In this way the metal ceramic substrate can be further processed without a metal paste printing and/or a cleaning procedure. This allows a further component, for example, a chip, a switch, a lighting element, a capacitor, a resistor or suchlike to be applied to the substrate or metal deposit in a simplified manner and fastened there, for example, without the use of auxiliary substances such as, for example, fluxes, cleaning agents and suchlike.

In one form of embodiment the metal deposit comprises a solderable or sinterable metal or a solderable or sinterable alloy. The metal deposit can also be understood as a solder or sinter deposit and have a certain volume or be a metal/alloy layer. The metal deposit can be a solderable or sinterable metal or a solderable or sinterable alloy.

In one form of embodiment the adhesive point is smearable at room temperature. Smearable means that after application to the metal deposit, the adhesive point may be partially dry, for example, but does not become solid or hard in air and remains sticky or smeary. The smearable adhesive point is neither completely solid nor completely fluid. It can have a certain viscosity so that, for example, a further component applied to the adhesive point cannot move by itself or slide by itself even in the case of a, for example, 90° inclined position of the substrate.

However, the substrate can also comprise a metal deposit and also an adhesive point on both sides. This means that the substrate can have a metal deposit and an adhesive point both on its upper side and also on its underside. The first and the second shell can be set up in such a way that the adhesive point directed upwards in the vertical direction (perpendicularly to the substrate surface) does not come into contact with the outer base side of the second shell and the vertically downwards directed adhesive point does not come into contact with the inner base side of the first shell.

In one form of embodiment the first shell and/or the second shell has/have at least one spacer for support on the other shell and/or on the substrate. The spacer can be formed, for example, on at least one wall of the first and/or the second shell in order to be supported on the respective other shell. Alternatively, the outer base side of the second shall can be supported on the spacer of the first shell. The space can be, for example, be formed in a point-like, web-like, cone-like or similar manner or extend along the wall of the first and/or the second shell.

In one form of embodiment the first shell comprises a base and a circumferential wall, and the circumferential wall extends from the base up to a wall height that is between the height of the substrate and double the height of the substrate. In other words, the wall height is greater than the height or thickness of one substrate and smaller than the height or thickness of two substrates. In other words, the first shell can be configured so that it can only receive one substrate and not two substrates. This can mean that the wall height is as great as the height or thickness of the substrate plus a safety margin. More precisely, the wall can be of a height that is at least a sum of the height of the substrate, metal deposit, adhesive point and safety margin. The safety margin can be 50 μm, for example. The wall of the first shell can have a height of between 200 and 1000 μm.

The base of the first shell can, for example, be of a rectangular shape in order to receive a substrate which is essentially rectangularly configured. The circumferential wall of the first shell can stand perpendicularly to the base of the shell or gradually widen out from the base in the direction of a free end of the shell. In one form of embodiment, the circumferential wall has a smaller outer dimension in the direction of the base than at its free end. In other words, the circumferential wall of the first shell can be conical design so that the wall widens out in the direction of a free end of the shell. In this way, the second shell can be simply separated from the first shell.

In one form of embodiment the first shell has at least one fastening element for the lateral fastening of the substrate relative to the first shell and/or the second shell. The fastening element can prevent the substrate being moved or laterally compressed during transportation. The fastening element can simultaneously also be a spacer for support on the respective other shell and/or the substrate. The fastening element can be formed in a point-like, web-like, conical or similar manner

In one form of embodiment the first shell and the second shell are identical in construction. However, the first and the second shell can also be differently configured, for example, in terms of the size and position of the metal deposit and the adhesive point.

In one form of embodiment the substrate comprises a plurality of individual substrates arranged next to each other. The individual substrate can in the form of an above-described substrate. Alternatively, it is also possible for a substrate to have one or more (preferably rectilinear) predetermined break lines which divide the substrate into two or more sections.

In one form of embodiment the first shell and the second shell are made of plastic or cardboard. In this way, the shells are cost-effective, lightweight and simple to manufacture. However, the first and the second shell can also be made of different materials. The materials can be transparent.

In one form of embodiment agent the packaging unit comprises a further substrate which is inserted into the second shell. The packaging unit can, of course, comprise a plurality of alternately arranged substrates and shells. In this way, substrates and shells can be stacked in a space-saving manner A shell placed on the upper end of the packaging units can form a conclusion of the packaging unit.

The present invention also comprises a package stack comprising a plurality of packaging units stacked on top of each other. Through a relatively flat configuration of the substrate and the shell, it is possible for a plurality of substrates and shells to be stacked on top of each other in a space-saving manner The spacers of the first and second shell can make it possible for the adhesive points on the metal deposits to remain untouched in spite of the stacking of several substrates and shells. Depending on the purpose of use and the storage capacity, the package stack can comprise any number of packaging units.

In one form of embodiment the package stack comprises a stabilising element which forms the conclusion of the package stack. The stabilising element can, for example, be a further shell on which no further substrate is placed. Alternatively, the stabilising element can also be a cover or a foil which forms the conclusion of the package stack. The stabilising element can act as a protective cover and, if the package stack is vacuum sealed, can remain stable in a vacuum without bending.

The present invention also covers a process for packaging a substrate. The process involves the following steps:
provision of a first shell,
insertion of a substrate into the first shell, and
mounting a second shell on the first shell.

A first side of the substrate is surrounded by the first shell and an opposite, second side of the substrate is covered by the second shell, wherein a metal deposit is applied to the second side of the substrate and an adhesive point is arranged on the metal deposit. The second shell is supported on the first shell in such a way that the second shell is only in contact with the substrate outside the adhesive point.

Further features, advantages and application possibilities of the present invention are set out in the following description, the examples of embodiment and the figures. All described and/or visually shown features can be combined with each other irrespective of their depiction in the individual claims, figures, sentences or paragraphs. In the figures, the same reference numbers denote identical or similar objects.

### BRIEF DESCRIPTION OF THE FIGURES

FIG. 1 shows a packaging unit according to one form of embodiment.

FIG. 2 shows a packaging unit according to one form of embodiment.

FIG. 3 shows a metal-ceramic substrate according to one form of embodiment.

FIG. 4 shows a package stack according to one form of embodiment.

### DETAILED DESCRIPTION OF THE EXAMPLES OF EMBODIMENT

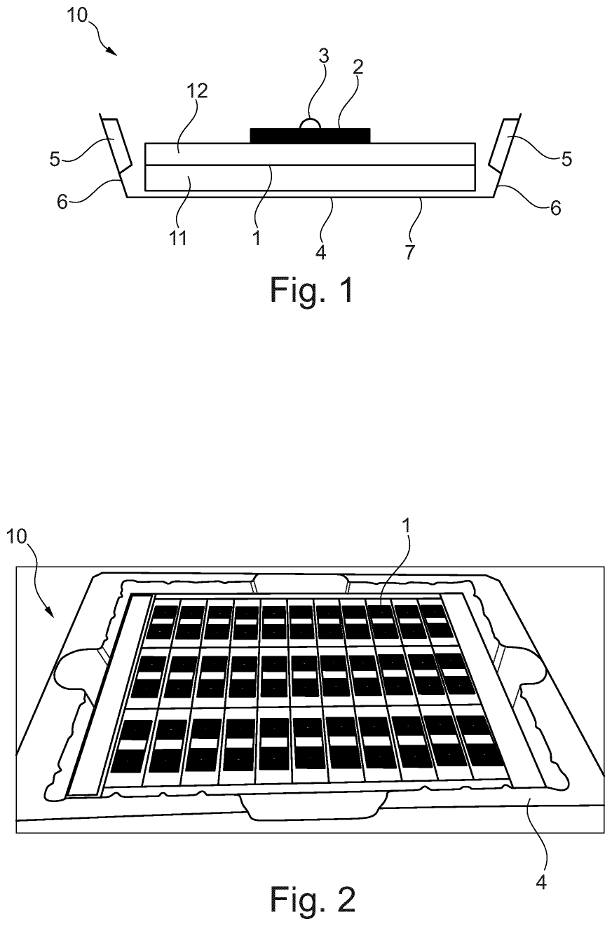

FIG. 1 and FIG. 2 show a packaging unit 10 for a metal-ceramic substrate 1. The packaging unit 10 comprises a first shell 4, a second shell 4′ (in FIG. 4) and a substrate 1. The substrate 1 can be produced by a direct copper bonding (DCB) process or direct aluminium bonding (DAB) process and can comprise a plurality of individual substrates arranged next to each other. The substrate 1 is inserted into the first shell 4, and the second shell 4′ (in FIG. 4) is mounted on the first shell 4 so that an underside of the substrate 1 is surrounded by the first shell 4 and an opposite, upper side of the substrate 1 is covered by the second shell 4′.

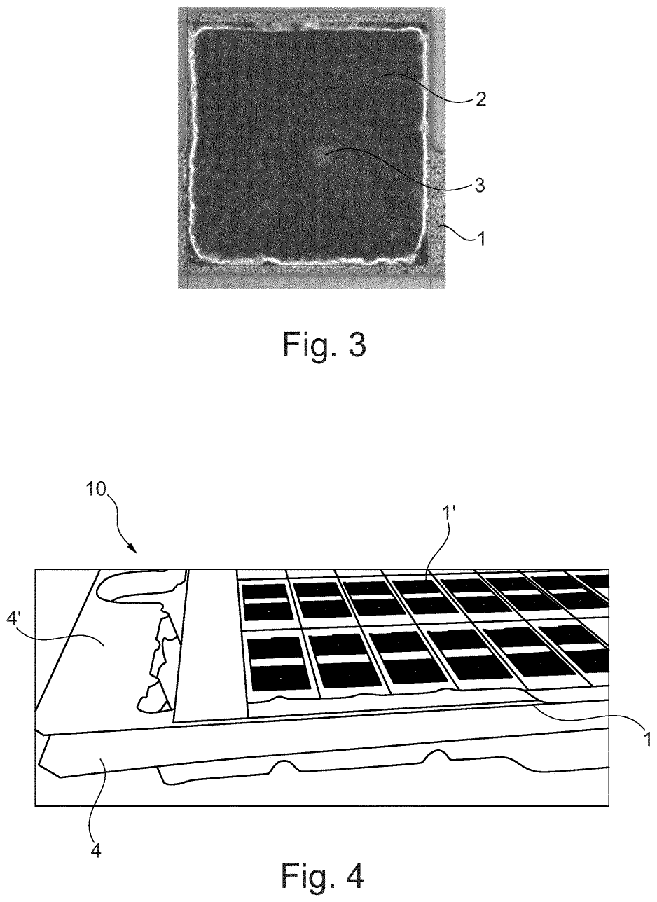

The substrate 1 comprises a ceramic layer 11 and at least one metallising layer 12. The substrate 1 preferably comprises a total of two metallising layers, namely the metallising layer 12 and a further metallising layer, which is not shown, on the other side of the ceramic layer 11. As also shown in FIG. 3, a metal deposit 2 is applied to the upper side of the metallising layer 12 of the substrate 1 and an adhesive point 3 is arranged on the metal deposit 2. The metal deposit 2 comprises a solderable or sinterable metal or a solderable or sinterable alloy. At room temperature and/or in air, the adhesive point 3 is sticky and smearable. An electronic component, for example a chip, lamp, resistor, capacitor etc. can be applied to the adhesive point.

The first shell and the second shell 4, 4′ can be designed identically and be made of plastic or cardboard. The first and the second shell 4, 4′ comprise a base 7 and a circumferential wall 6. The circumferential wall 6 extends from the base 7 to a wall height at which only a substrate 1 plus a safety margin are surrounded. The circumferential wall 6 has a smaller outer dimension in the direction of the base 7 than at its free end. The first shell 4 and/or the second shell 4′ has/have at least one spacer 5 for support on the respective other shell and/or on the substrate 1. Furthermore, the first and the second shell 4, 4′ can comprise a fastening element (not shown) for the lateral fastening of the substrate 1 relative to the first shell 4 and/or to the second shell 4′. The fastening element can, for example, be an extended spacer or arranged separately on the ceramic layer 11 or metallising layer 12. When the second shell 4′ is placed on the first shell 4, the second shell 4′ should be supported on the first shell 4 in such a way that the second shell 4′ only contacts the substrate 1 outside the adhesive point 3.

As shown in FIG. 4, the packaging unit 10 can also comprise a further substrate 1′ which is placed on the second shell 4′. In this way a package stack can be produced which comprises a plurality of packaging units 10 stacked on top of each other and can store and/or transport them in a space-saving manner without contacting the adhesive points of the substrate. The package stack can also comprise a stabilising element (not shown) which forms the conclusion of the package stack.

It is additionally pointed out that “comprising” and “having” do not rule out other elements or steps, and “a” or “an” do not rule out a plurality. It is also pointed out that features or steps which have been described with reference to the above examples of embodiment can also be used in combination with other features or steps of other examples of embodiment described above. Reference numbers in the claims should not be considered as restrictions.

1. A packaging unit for a substrate, comprising:
a first shell,
a substrate, and
a second shell,
wherein the substrate is placed in the first shell, and the second shell is mounted on the first shell so that a first side of the substrate is surrounded by the first shell and an opposite, second side of the substrate is covered by the second shell,
wherein a metal deposit is applied to the second side of the substrate and an adhesive point is arranged on the metal deposit, and
wherein the second shell is supported on the first shell in such a way that the second shell is only in contact with the substrate outside the adhesive point.

2. Packaging The packaging unit according to claim 1, wherein the substrate is a metal-ceramic substrate.

3. The packaging unit according to claim 2, wherein the metal-ceramic substrate comprises a ceramic layer and at least one metallisation layer and the metal deposit is applied to the metallisation layer.

4. The packaging unit according to claim 1, wherein the metal deposit can be a solderable or sinterable metal or a solderable or sinterable alloy.

5. The packaging unit according to claim 1, wherein the first shell and/or the second shell has/have at least one spacer for support on the respective other shell and/or on the substrate.

6. The packaging unit according to claim 1, wherein the first shell comprises a base and a circumferential wall, and
wherein the circumferential wall extends from the base up to a wall height that is between the height of the substrate and double the height of the substrate.

7. The packaging unit according to claim 6, wherein the circumferential wall has a smaller outer dimension in the direction of the base than at its free end.

8. The packaging unit according to claim 1, wherein the first shell and the second shell are identical in construction.

9. The packaging unit according to claim 1, wherein the adhesive point is designed for fastening an electronic component on the substrate.

10. The packaging unit according to claim 1, wherein the substrate comprises a plurality of individual substrates arranged next to each other.

11. The packaging unit according to claim 1, wherein the first shell and the second shell are made of plastic or cardboard.

12. The packaging unit according to claim 1, also comprising a further substrate which is inserted into the second shell.

13. A package stack comprising a plurality of packaging units according to claim 1 stacked on top of each other.

14. The package stack according to claim 13, further comprising a stabilising element which forms the conclusion of the package stack.

15. A process for packaging a substrate comprising the following steps:
providing a first shell,
inserting a substrate into the first shell, and
mounting a second shell on the first shell,
so that a first side of the substrate is surrounded by the first shell and an opposite, second side of the substrate is covered by the second shell,
wherein a metal deposit is applied to the second side of the substrate and an adhesive point is arranged on the metal deposit, and
wherein the second shell is supported on the first shell in such a way that the second shell is only in contact with the substrate outside the adhesive point.
